(19) United States
(12) Patent Application Publication
(10) Pub. No.: US 2021/0021179 A1
(43) Pub. Date: Jan. 21, 2021

(54) CIRCUIT ARRANGEMENT HAVING A SPACER ELEMENT, CONVERTER AND AIRCRAFT WITH SUCH A CIRCUIT ARRANGEMENT, AND METHOD FOR CURRENT MEASUREMENT

(71) Applicants: Rene Blank, Berlin (DE); Martin Franke, Berlin (DE); Peter Frühauf, Falkensee (DE); Matthias Heimann, Potsdam (DE); Nora Jeske, Berlin (DE); Rüdiger Knofe, Teltow (DE); Bernd Müller, Falkenberg (DE); Stefan Nerreter, Heidesee OT Blossin (DE); Jörg Strogies, Berlin (DE); Klaus Wilke, Berlin (DE); Ulrich Wittreich, Velten (DE)

(72) Inventors: Rene Blank, Berlin (DE); Martin Franke, Berlin (DE); Peter Frühauf, Falkensee (DE); Matthias Heimann, Potsdam (DE); Nora Jeske, Berlin (DE); Rüdiger Knofe, Teltow (DE); Bernd Müller, Falkenberg (DE); Stefan Nerreter, Heidesee OT Blossin (DE); Jörg Strogies, Berlin (DE); Klaus Wilke, Berlin (DE); Ulrich Wittreich, Velten (DE)

(21) Appl. No.: 17/042,581

(22) PCT Filed: Feb. 28, 2019
(86) PCT No.: PCT/EP2019/054943

§ 371 Date: Sep. 28, 2020

(30) Foreign Application Priority Data
Mar. 29, 2018 (DE) 10 2018 204 865.7

(51) Int. Cl. H02K 11/33; H05K 7/20; H01L 23/00; H01L 23/367; H01L 23/373; H01L 23/16; B64D 27/24; B64D 35/02

(52) U.S. Cl. CPC H02K 11/33; H05K 7/209; H01L 24/32; H01L 23/367; H01L 23/3735; H01L 23/16; H02K 2211/03; B64D 35/02; H01L 2224/32225; H01L 2924/14252; H01L 2924/15747; H01L 2924/15787; B64D 27/24

(57) ABSTRACT

A circuit arrangement is disclosed herein. The circuit arrangement includes a circuit carrier board, a power semiconductor arranged on the underside of the circuit carrier board, and a wiring carrier board arranged underneath the power semiconductor. The circuit arrangement further includes a metallic first spacer element arranged between the circuit carrier board and the wiring carrier board and via which an electric load current from the power semiconductor flows, wherein the first spacer element acts as a shunt through which current flows. The circuit arrangement further includes a voltage measuring unit, by which a voltage drop across the first spacer element, produced by the load current flow, may be determined. A converter having such a circuit arrangement, an aircraft having a converter, and a method for current measurement in power semiconductors are likewise specified.

The present patent document is a § 371 nationalization of PCT Application Serial No. PCT/EP2019/054943, filed Feb. 28, 2019, designating the United States, which is hereby incorporated by reference, and this patent document also claims the benefit of German Patent Application No. 10 2018 204 865.7, filed Mar. 29, 2018, which is also hereby incorporated by reference.

### TECHNICAL FIELD

The disclosure relates to a circuit arrangement having a circuit carrier board, a power semiconductor arranged on the underside of the circuit carrier board, and a wiring carrier board arranged underneath the power semiconductor. The disclosure also relates to a converter with such a circuit arrangement and to an aircraft, (e.g., an airplane), having a converter. The disclosure also relates to a method for measuring the current in a power semiconductor.

### BACKGROUND

External monitoring devices are currently required for the monitoring and control of power semiconductors in converters. These have to be created separately in the design phase (e.g., electrical, mechanical) and consume space accordingly, causing additional weight and costs. In a specific case, a load current may be determined directly on the power semiconductor.

Such a monitoring is necessary to detect the failure of individual components, to synchronize subsystems, to compensate for drift (e.g., due to temperature, aging, etc.), and to compensate for component scatter.

As is known, this monitoring may be resolved through “binning” of the semiconductors to compensate for scatter effects, or through installation of current sensors, such as Hall sensors (e.g., contactless) or shunts (e.g., connected in series), with corresponding evaluation electronics. These sensors are required in every power path of a system (e.g., at least for every semiconductor chip). Alternatively, there may be no monitoring at all, with the disadvantage that the above-mentioned monitoring functions are not possible. The result is sudden (e.g., unexpected) failures, poorer electrical performance, drift (e.g., aging), etc.

A converter, also known as an inverter, refers to a power converter that converts an AC voltage or a DC voltage into an AC voltage with a modified frequency and amplitude. Converters may be configured as AC/DC-DC/AC converters or DC/AC converters, wherein an output AC voltage is generated from an input AC voltage or an input DC voltage via a DC link and clocked semiconductors.

### SUMMARY

It is an object of the disclosure to specify a solution for simple and space-saving current measurement for power semiconductors in converters.

According to the disclosure, the object addressed is achieved with the circuit arrangement, the converter, the aircraft, and the method disclosed herein. The scope of the present disclosure is defined solely by the appended claims and is not affected to any degree by the statements within this summary. The present embodiments may obviate one or more of the drawbacks or limitations in the related art.

In a design variant, the power semiconductors are prefabricated with a carrier ceramic (CKV) and then joined to a circuit carrier (e.g., soldering, sintering). In addition to the power semiconductor chip, which is contacted in this manner on its second side, further contacts are implemented.

This is achieved using so-called change-overs that act as spacers, e.g., conductive elements which roughly correspond in height to the power semiconductor chip and are also joined in addition to the chip (if necessary, simultaneously with the chip by soldering or sintering). In the simplest case, the change-overs are metallic formed parts (e.g., punched parts).

If a current path to be measured is routed through these change-overs, it may be used for current measurement by tapping the electrical potential directly above and directly below and then feeding it to a voltage measuring device. In this case, the change-over is used as a shunt at the same time, because it is required anyway and is arranged in the current path (e.g., series circuit).

A circuit arrangement is disclosed herein. The circuit arrangement has a circuit carrier board, a power semiconductor arranged on the underside of the circuit carrier board, and a wiring carrier board arranged underneath the power semiconductor. The circuit arrangement also includes a metallic first spacer element (=change-over) arranged between the circuit carrier board and the wiring carrier board and through which an electrical load current of the power semiconductor flows. The first spacer element acts as a shunt through which current flows. The circuit arrangement also includes a voltage measuring unit through which a voltage drop across the first spacer element, produced by the load current flow, may be determined.

The disclosure offers the advantage of measuring a load current in a simple and space-saving manner.

In an extension, the height of the first spacer element may be approximately the same as the height of the power semiconductor.

In another embodiment, the circuit carrier board may be a DCB-substrate board.

The circuit arrangement may also have electrical and/or electronic assemblies arranged on the top of the circuit carrier board.

In a further embodiment, a heat sink may be arranged on the top of the circuit carrier board.

In addition, a second metal spacer element (=change-over) may be arranged between the circuit carrier board and the wiring carrier board, via which the power semiconductor may be activated and/or the current measurement controlled.

A converter with a circuit arrangement is also disclosed herein.

In addition, an aircraft with a converter and an electric motor as an electric drive of the aircraft is also disclosed herein, wherein the electric motor may be supplied with electrical energy by the converter.

The aircraft may have a propeller driven by the electric motor.

Finally, a method is disclosed for measuring current in a power semiconductor having a circuit arrangement, wherein the load current of the power semiconductor is passed through the first spacer element and the voltage drop across the first spacer element due to the load current is determined.

### BRIEF DESCRIPTION OF THE DRAWINGS

Further special features and advantages of the disclosure are described in the following explanations of an exemplary embodiment using schematic drawings.

FIG. 1 depicts an example of a circuit arrangement with current measurement.

FIG. 2 depicts an example of a block diagram of a converter.

FIG. 3 depicts an example of an aircraft with an electric drive.

### DETAILED DESCRIPTION

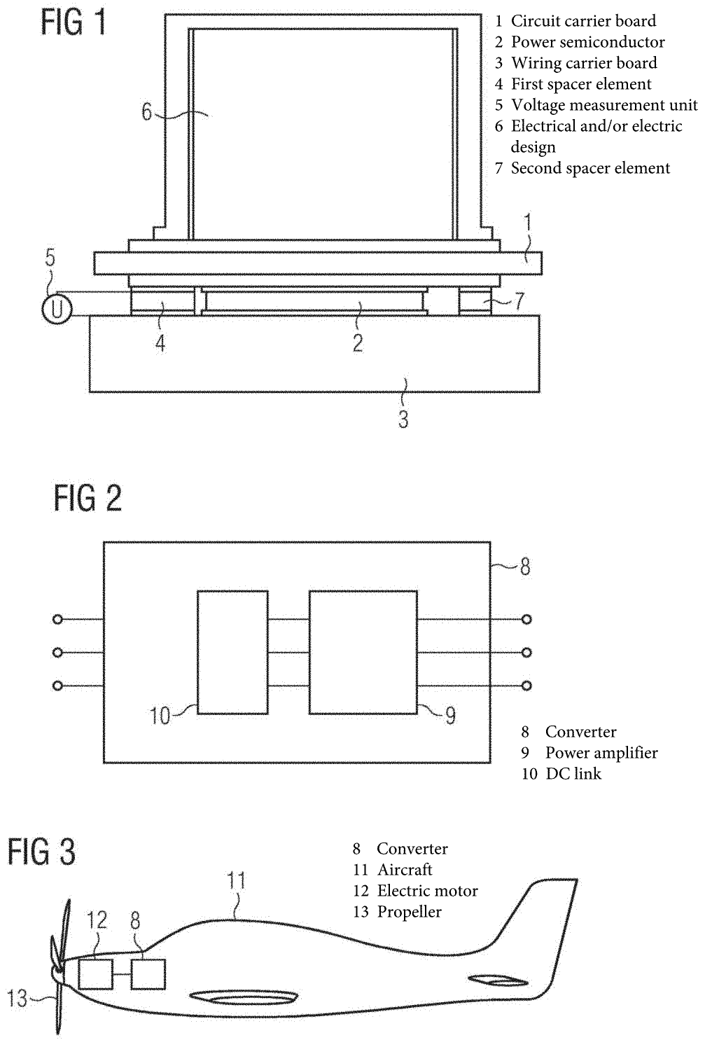

FIG. 1 shows a circuit arrangement with a circuit carrier board 1, on the underside of which an example of a power semiconductor 2 is arranged. For example, the circuit carrier board 1 is a DCB circuit board including an insulating ceramic carrier and copper coatings. In addition to the power semiconductor 2, a first spacer element 4 and a second spacer element 7 are arranged on the circuit carrier board 1. The two spacer elements 4, 7 have approximately the same overall height as the power semiconductor 2 and are contacted with a wiring board 3 arranged parallel to the circuit carrier board 1.

The load current of the power semiconductor 2 flows through the metallic first spacer element 4. The first spacer element 4 has a defined, known resistance and is used as a shunt for current measurement. To determine the load current, the voltage drop along the first spacer element 4 is determined using the voltage measuring unit 5, and the load current is determined from this. The first spacer element 4 is also referred to as a “change-over” because the current path “changes over” from the wiring carrier board 3 to the circuit carrier board 1.

Electrical or electronic assemblies 6, or simply heat sinks, are arranged on the side of the circuit carrier board 1 facing the power semiconductor 2.

The power semiconductor 2 may be activated and/or the current measurement may be controlled by the metallic second spacer element 7.

FIG. 2 shows a highly simplified block diagram of a converter 8 which has a DC link 10 and a power amplifier 9. The power amplifier 9 has a circuit arrangement according to FIG. 1.

FIG. 3 shows a highly simplified drawing of an electrically powered aircraft 11, (e.g., an airplane). The aircraft 11 has a propeller 13 driven by an electric motor 12. The electric motor 12 is supplied with electrical energy by the converter 8. The converter 8 is designed in accordance with the arrangements according to FIG. 1 and FIG. 2.

Although the disclosure has been illustrated and described in greater detail by the exemplary embodiments, the disclosure is not restricted by the examples disclosed, and other variations may be derived therefrom by the person skilled in the art without departing from the scope of protection of the disclosure.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A circuit arrangement comprising:
a circuit carrier board;
a power semiconductor arranged on an underside of the circuit carrier board;
a wiring carrier board arranged underneath the power semiconductor;
a first metallic spacer element arranged between the circuit carrier board and the wiring carrier board and via which an electric load current from the power semiconductor is configured to flow, wherein the first metallic spacer element is configured to act as a shunt through which current flows; and
a voltage measuring unit configured to determine a voltage drop across the first metallic spacer element, wherein the voltage drop is produced by the load current flow.

2. The circuit arrangement of claim 1, wherein a height of the first metallic spacer element corresponds to a height of the power semiconductor.

3. The circuit arrangement of claim 1, wherein the circuit carrier board is a DCB-substrate board.

4. The circuit arrangement of claim 1, further comprising:
electrical and/or electronic assemblies arranged on a top of the circuit carrier board.

5. The circuit arrangement of claim 4, further comprising:
heat sinks arranged on the top of the circuit carrier board.

6. The circuit arrangement of claim 5, further comprising:
a second metallic spacer element arranged between the circuit carrier board and the wiring carrier board, and via which the power semiconductor is configured to be activated and/or a current measurement is configured to be controlled.

7. A converter comprising:
a circuit arrangement having:
a circuit carrier board;
a power semiconductor arranged on an underside of the circuit carrier board;
a wiring carrier board arranged underneath the power semiconductor;
a first metallic spacer element arranged between the circuit carrier board and the wiring carrier board and via which an electric load current from the power semiconductor is configured to flow, wherein the first metallic spacer element is configured to act as a shunt through which current flows; and
a voltage measuring unit configured to determine a voltage drop across the first metallic spacer element, wherein the voltage drop is produced by the load current flow.

8. An aircraft comprising:
a converter having a circuit arrangement comprising:
a circuit carrier board;
a power semiconductor arranged on an underside of the circuit carrier board;
a wiring carrier board arranged underneath the power semiconductor;
a first metallic spacer element arranged between the circuit carrier board and the wiring carrier board and via which an electric load current from the power semiconductor is configured to flow, wherein the first metallic spacer element is configured to act as a shunt through which current flows; and
a voltage measuring unit configured to determine a voltage drop across the first metallic spacer element, wherein the voltage drop is produced by the load current flow; and
an electric motor as an electric drive of the aircraft,
wherein the electric motor is configured to be supplied with electrical energy by the converter.

9. The aircraft of claim 8, further comprising:
a propeller configured to be driven by the electric motor.

10. A method for current measurement comprising:
providing a circuit arrangement having a circuit carrier board, a power semiconductor arranged on an underside of the circuit carrier board, a wiring carrier board arranged underneath the power semiconductor; a first spacer element arranged between the circuit carrier board and the wiring carrier board, and a voltage measuring unit;
passing a load current of the power semiconductor through the first spacer element; and
determining, using the voltage measuring unit, the voltage drop across the first spacer element due to the load current.

11. The method of claim 10, further comprising:
activating the power semiconductor by a second spacer element of the circuit arrangement, wherein the second spacer element is arranged between the circuit carrier board and the wiring carrier board of the circuit arrangement.

12. The method of claim 11, further comprising:
controlling the current measurement by the second spacer element.

13. The method of claim 10, further comprising:
controlling the current measurement by a second spacer element of the circuit arrangement, wherein the second spacer element is arranged between the circuit carrier board and the wiring carrier board of the circuit arrangement.

14. The circuit arrangement of claim 1, further comprising:
heat sinks arranged on a top of the circuit carrier board.

15. The circuit arrangement of claim 1, further comprising:
a second metallic spacer element arranged between the circuit carrier board and the wiring carrier board, and via which the power semiconductor is configured to be activated and/or a current measurement is configured to be controlled.

16. The aircraft of claim 8, wherein the circuit arrangement of the aircraft further comprises:
electrical and/or electronic assemblies arranged on a top of the circuit carrier board.

17. The aircraft of claim 16, wherein the circuit arrangement of the aircraft further comprises:
heat sinks arranged on the top of the circuit carrier board.

18. The aircraft of claim 17, wherein the circuit arrangement of the aircraft further comprises:
a second metallic spacer element arranged between the circuit carrier board and the wiring carrier board, and via which the power semiconductor is configured to be activated and/or a current measurement is configured to be controlled.
